(19) United States
(12) Patent Application Publication
(10) Pub. No.: US 2005/0186796 A1
(43) Pub. Date: Aug. 25, 2005

(54) Method for gap filling between metal-metal lines

(75) Inventors: Ping-Wei Lin, Hsin-Chu City (TW); Chao-Sheng Chiang, Hsin-Chu City (TW); Kuo-Chuan Kuo, Chi-Lung City (TW)

Correspondence Address: INTELLECTUAL PROPERTY SOLUTIONS, INCORPORATED, 5717 COLFAX AVENUE, ALEXANDRIA, VA, 22311, US

(73) Assignee: SiS MICROELECTRONICS CORPORATION

(21) Appl. No.: 10/784,186

(22) Filed: Feb. 24, 2004

(51) Int. Cl. H01L 21/469; H01L 21/473

(52) U.S. Cl. 438/688; 438/694; 438/654; 438/788

(57) ABSTRACT

A method for gap filling between metal-metal lines is provided so that a first dielectric layer forms on a surface and side wall of a plurality of metal lines thereon which is called partially HDP deposition. Then, a portion of the first dielectric layer is removed by a high-density plasma with Ar/O₂ to sputter so that a portion of side wall of metal lines is exposed. Afterwards, a second dielectric layer is formed on the first dielectric layer by a method of high density plasma oxide deposition so that the metal lines are completely covered.

### BACKGROUND OF THE INVENTION

1. Field of the Invention

This invention relates to a method of gap filling between metal-metal lines, and more particularly to utilize a method of HDP-IMD in the back end process to fill a gap between metal-metal lines.

2. Description of the Prior Art

Generally, as semiconductor dimensions continue to shrink and device densities increase, the depositing technique in the back end process of ultra large scale integration (ULSI) can not achieve the gap fill without voids because of the shrinkage in the gap between metal-metal lines. However, a method of high density plasma-chemical vapor deposition (HDP-CVD) is utilized to fill the narrow gap and to prevent the production of voids due to its excellent ability in filling the gap. Consequently, the oxide is generally decomposed to be a material of inter-metal dielectric and passivation for filling the gap between the metal-metal lines.

The HDP-CVD is the method of chemical vapor deposition for executing the depositing and etching process in the meantime. When the size of pattern is reduced, the width of the metal line and the gap between the metal lines are become smaller. However, due to the fact that the resistor of the metal line can not be increased so that the height of the metal line can not be relatively decreased, and therefore causes a bigger aspect ratio. Accordingly, it makes a larger challenge in the process of inter-metal dielectric (IMD) deposition.

FIGS. 1A to 1B is the conventional diagram to fill the gap between the metal-metal lines with HDP oxide as the material in the IMD layer. As shown in FIG. 1A, providing a semiconductor structure 101 at first, and then to form a first inter-metal dielectric layer 103 thereon. After that, a plurality of metal lines 107 are formed on the first dielectric layer 103, wherein the material of the metal lines 107 is Al alloy or AlCu alloy etc. Moreover, a glue layer 105 is formed on the underside of the metal lines 107 to provide a way to adhere the metal lines 107 and the first dielectric layer 103. Next, an anti-reflection layer (ARC) is formed on the top of the metal lines 107. Finally, a second inter-metal dielectric layer 111 is formed between a plurality of gaps between the metal lines 107 to be used as an isolation with other metal lines on other thin films.

The method for depositing the second inter-metal dielectric layer 111 utilizes a method for depositing a thin film, for instance HDP-CVD. Nevertheless, when the integrity of the devices become higher and the aspect ratio of the gap become larger, an overhang is easily produced while depositing the thin film, as a result the device has variable geometric shapes thereon, and the material's low migration. When the second inter-metal dielectric layer 111 is depositing, the rate of deposition is quite different at different positions, for instance the top of the hole with a bigger arriving angle has faster rate for depositing, but the bottom of the hole with the smaller arriving angle has a slower one. If the material has a reaction as soon as it absorbs on the device and not migrate anywhere, the top of the hole with the bigger arriving angle will have an overhang. Therefore, when the thickness of the film is getting enhanced, the overhang is getting bigger due to the arriving angle effect and material's low migration and HDP process re-deposition issue. Accordingly, the gap between the metal-metal lines will be quickly sealed so that causes the voids 113 produced inside the gap, as shown in FIG. 1B. The voids will make the device open and influence the reliability of the device.

As mentioned above, due to the fact that the conventional method of HDP-IMD does not have the ability in satisfactorily filling the gap and the advanced process, and as a result, a problem with producing the voids in the gap between the metal-metal lines occurs. Therefore, an improved method of filling the gap between the metal-metal lines is necessary to require in order to overcome the problems of the process in the prior art.

### SUMMARY OF THE INVENTION

According to the background of the invention as in the prior art, some drawbacks in the process of filling the gap occurs, therefore this invention makes efforts in the improvement of the process for filling the gap between the metal-metal lines. Hence, the present invention is provided.

To resolve the problem with the voids in the gap between the metal-metal lines while gap filling, the present invention provides a method of HDP-IMD process, which improves the ability in filling of the gap. It can satisfy the ability of filling the gap in the advanced process, and not damage the surface of the metal lines.

To resolve the problem with the voids in the gap between the metal-metal lines while gap filling, the present invention further provides a method of HDP-IMD process, which improves the ability in filling of the gap. It utilizes a recipe to accomplish the sputter and HDP silicon oxide deposition process in situ.

To resolve the problem with the voids in the gap between the metal-metal lines while gap filling, the present invention still provides a method of HDP-IMD process, which improves the ability in filling of the gap. It performs the deposition twice to avoid the voids producing in the gap.

According to the objectives as mentioned above, one embodiment provides a method of high density plasma-chemical vapor deposition which has high ability of gap filling that comprises the steps at least: providing a semiconductor structure, and the surface of the semiconductor structure has a plurality of metal lines thereon. Then, utilizing a first high density plasma to partially deposit a first dielectric layer on the surface and side wall of the plurality of metal lines. Afterwards, before forming the voids, a second high density plasma is utilized to remove a portion of the first dielectric layer until a portion of the side wall of metal lines are exposed, wherein the portion of the first dielectric layer is remained on the portion of the metal lines. Next, a second dielectric layer is deposited on the first dielectric layer by a third high density plasma and covering on the metal lines. The first high density plasma has the same composition with the third high density plasma that comprises an inert gas, an oxidative gas and a depositing gas.

### BRIEF DESCRIPTION OF THE DRAWINGS

The objectives and features of the present invention as well as advantages thereof will become apparent from the following detailed description, considered in conjunction with the accompanying drawings. It is to be understood, however, that the drawings, which are not to scale, are designed for the purpose of illustration and not as a definition of the limits of the invention, for which reference should be made to the appended claims.

The present invention can be the best understood through the following description and accompanying drawings, wherein:

FIG. 1A to 1B shows a schematically cross-sectional view of the various steps of a conventional method in filling a gap between the metal-metal lines thereof; and

FIG. 2A to 2D shows a schematically cross-sectional view of the various steps of the present invention that a method in filling a gap between the metal-metal lines according to a preferred embodiment of the present invention.

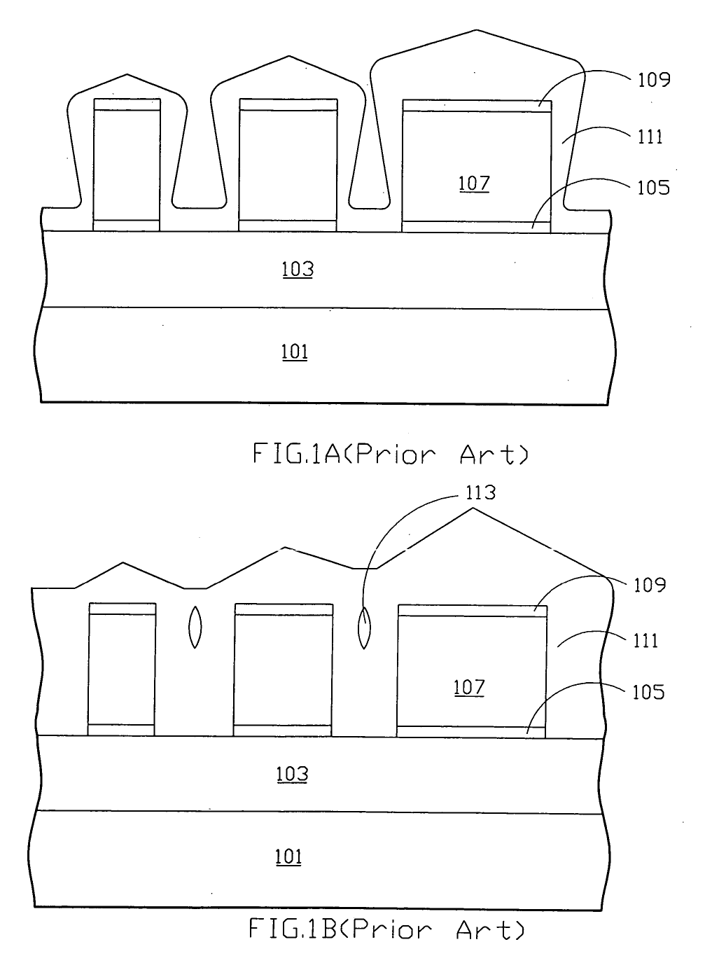

### DESCRIPTION OF THE PREFERRED EMBODIMENT

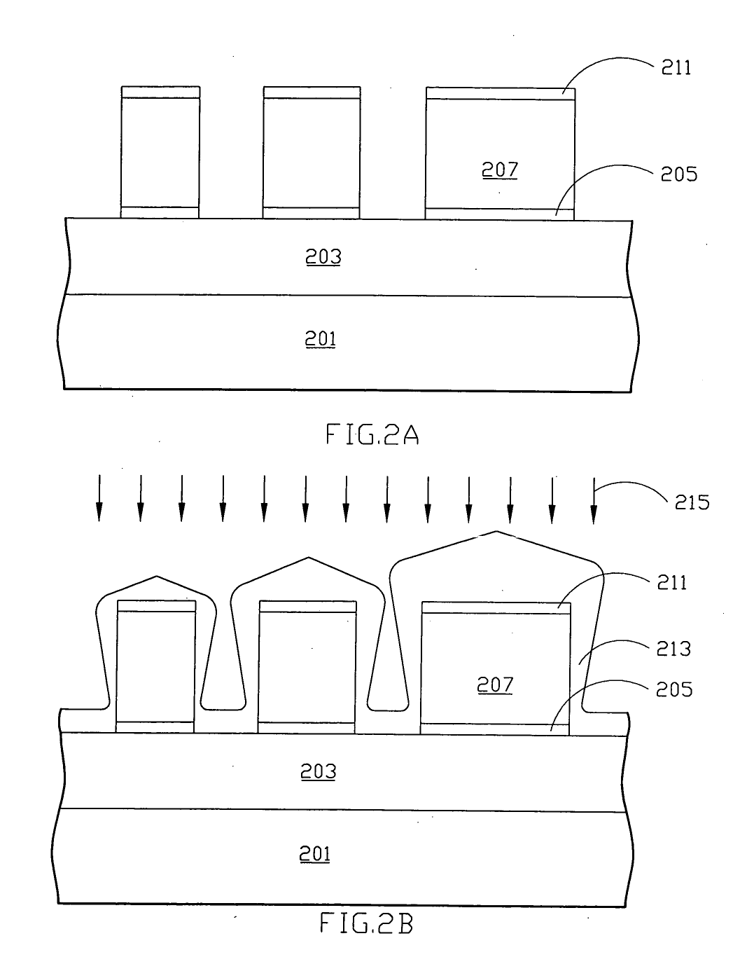

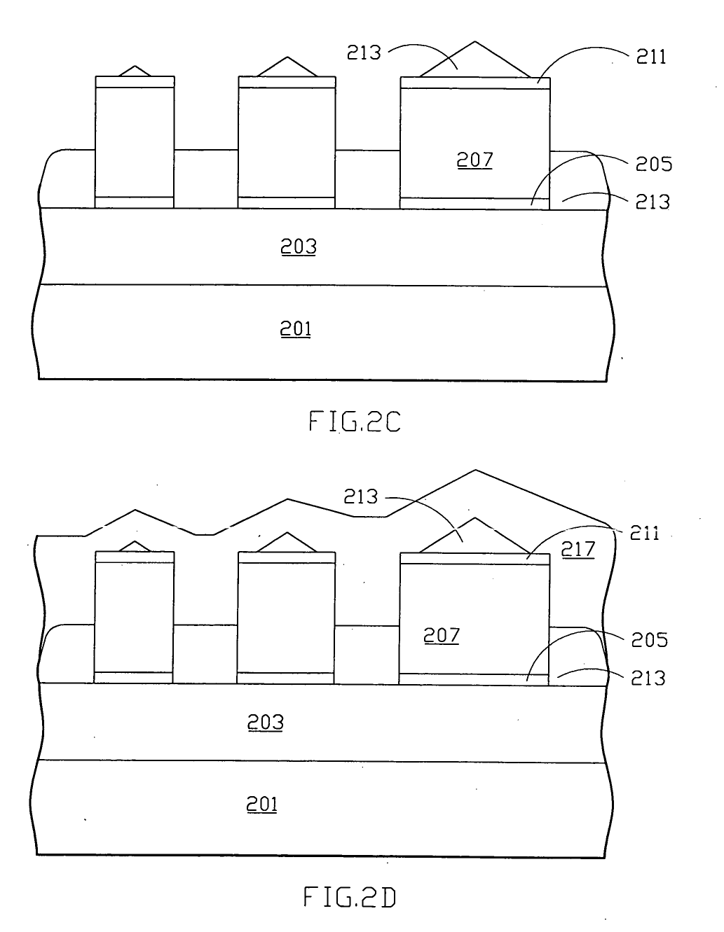

The preferred embodiment is explained with reference to the drawings of FIG. 2A to 2D. Referring to FIG. 2A that diagrams a semiconductor structure formed in a back end process. At first, a semiconductor substrate 201 is provided, and then an inter-metal dielectric layer 203 is formed on the semiconductor substrate 201. Next, a plurality of metal lines 207 is formed on the surface of the inter-metal dielectric layer 203. The method for forming the plurality of metal lines is that utilizes a method of deposition, such as plasma enhanced chemical vapor deposition (PECVD) process or high density plasma chemical vapor deposition (HDPCVD) process that fills a metal layer into a hole produced by a method of dry etching, and covering on the surface of the external hole, wherein the material of the hole is a dielectric such as silicon dioxide (SiO₂). After that, performing a planarization to the metal layer filled in the hole, by a method of chemical mechanical polish (CMP), and removing the metal layer outside the hole until the surface of the hole is exposed. Finally, utilizing a way of etching to remove the dielectric layer outside the hole in order to accomplish the semiconductor structure in the back end process, wherein the material of the plurality of metal lines 207 is AlCu alloy or Al alloy etc.

Besides, an adhesive layer 205 is formed on the underside of the metal lines 207 before forming the plurality of metal lines 207, for instance titanium nitride (TiN) layer that provides a way of adhesive with the inter-metal dielectric layer 203, and then the process for depositing metal lines 207 is performed. Moreover, in order to avoid influencing the process with a light reflection by the metal layer, an anti-reflection layer (ARC) 211 is formed on the top of the metal lines 207, for instance a silicon-oxy-nitride (SiOₓN_{y}) layer that ensures the accuracy in the process of mask transferring.

Following that, performing the first step of gap filling in the present invention, please refer to FIG. 2B. As shown in FIG. 2B, forming the semiconductor structure that the plurality of metal lines 207 are formed on the surface of the inter-metal dielectric layer 203. After that, the semiconductor structure is placed into a chamber to partially deposit a first dielectric layer 213 on the surface and side wall of the plurality of metal lines 207, for instance a silicon dioxide layer. The method for forming the first dielectric layer, utilizes a method of high density plasma-chemical vapor deposition (HDP-CVD), wherein comprises adding a first mixed gas. The first mixed gas comprises a first depositing gas such as silane (SiH₄), a first inert gas such as argon and an oxidative gas such as oxygen. When the frequency powers, such as low frequency radio frequency (LFRF) power and high frequency radio frequency (HFRF) power are both added to the first mixed gas, the first high density plasma is produced, and control in its direction with a bias voltage on an electrostatic chuck (ESC), that is, forming the first dielectric layer 213 on the surface and side wall of the plurality of metal lines 207. Therefore, before forming the voids within the gap, the first depositing gas is exhausted by a control value, and the RF power is turned off in the meanwhile so that a second mixed gas is produced in the chamber after that. The second mixed gas is mixed with a second inert gas such as argon and an oxidative gas such as oxygen. Following that, adding both the LFRF and Bias HFRF power to excite the second mixed gas, and producing a second high density plasma 215 controlled with the bias voltage on the electrostatic chuck (ESC) in the direction.

Subsequently, performing the second step of gap filling in the present invention, please refer to FIG. 2B. After forming the second high density plasma 215, the second high density plasma 215 is utilized to remove a portion of the first dielectric layer 213 until a portion of the metal lines are exposed by a way of physical sputter, such as a method of sputter back. In this embodiment, while sputtering the first dielectric layer 213 by the second high density plasma 215, the rate for etching the first dielectric layer 213 is faster than the anti-reflection layer's 211. Because the oxidative gas, such as oxygen, can enhance the etching selectivity with the first dielectric layer 213 to the anti-reflection layer 211 and the metal, so the portion of the first dielectric layer 213 is remained on some of the surface of the metal lines 207 with geometric shape that is similar to a triangle, and not damage the metal lines 207. It notes that the remained first dielectric layer 213 is distributed on the metal lines 207, which is less concentration. Besides, owing to the Ar/O₂ sputter yield in different angle issue, the etches for the overhang on the metal lines 207 is faster than the flat one on the metal lines 207. Hence, the first dielectric layer 213 remained on the surface of the bigger metal lines 207 is more than the first dielectric layer 213 remained on the smaller metal lines 207, as shown in FIG. 2C.

After removing the portion of the first dielectric layer 213, a third step in the present invention is performed, as shown in FIG. 2D. Providing a third mixed gas, which is mixed with a second depositing gas such as silane, a third inert gas such as argon and an oxidative gas such as oxygen. Utilizing both the LFRF and Bias HFRF power to produce a third high density plasma to form a second dielectric layer 217 on the first dielectric layer 213, and covering the plurality of metal lines 207 completely. The direction of the third high density plasma is controlled with the bias voltage on the electrostatic chuck (ESC), the second dielectric layer 217 is a silicon dioxide layer in addition.

Due to the fact that the present invention utilizes the method of high density plasma-chemical vapor deposition, and performing the “etching” and “deposition” processes in situ in the same chamber so that the film, which is deposited, has higher density. The first dielectric layer 213 is partially removed before depositing the second dielectric layer 217 so that the portion of the first dielectric layer 213 still remains within the gap between the metal lines 207 that causes the gap between the metal lines 207 has smaller aspect ratio. After that, the gap between metal lines 207 will be completely filled with no voids after depositing the second dielectric layer 207. Accordingly, the present invention can satisfy the ability of filling in advanced process, and accomplish the Ar/O₂ sputter and HDP silicon oxide deposition process in situ in the same chamber. It notes that the 1^{st} HDP oxide deposition and the following Ar/O₂ sputter process also can be performed in different chamber.

It notes that the method of filling in the present invention is not only utilized in filling the gap between the metal-metal lines, but also utilized in other methods for filling the notch such as the process of shallow trench isolation (STI). In other embodiments, the depositing gas, oxidative gas and inert gas are the same as in filling the gap between metal-metal lines. And the RF power is also added therein to produce the high density plasma, moreover; utilizing twice deposition to fill the notch and not produce voids.

The preferred embodiments are only used to illustrate the present invention, not intended to limit the scope thereof. Many modifications of the preferred embodiments can be made without departing from the spirit of the present invention.

1. A method for gap filling between metal-metal lines, comprising:
providing a semiconductor structure, a surface of said semiconductor structure has a plurality of metal lines thereon;
forming a first dielectric layer on a surface and a side wall of said plurality of metal lines by a first high density plasma;
removing said first dielectric layer until a portion of said side wall of said plurality of metal lines are exposed by a second high density plasma, wherein a portion of said first dielectric layer with a geometric shape is on some of said metal lines; and ‘forming a second dielectric layer on said first dielectric layer by a third high density plasma, and covering said plurality of metal lines thereon.

2. The method according to claim 1, further comprising an adhesive layer formed on said underside of said plurality of metal lines.

3. The method according to claim 2, further comprising an anti-reflection layer formed on top of said plurality of metal lines.

4. The method according to claim 3, wherein the material of said anti-reflection layer is silicon-oxy-nitride (SiOₓN_{y}).

5. The method according to claim 1, wherein the material of said plurality of metal lines is selected from the group consisting of AlCu alloy and Al alloy.

6. The method according to claim 1, wherein the material of said first dielectric layer is silicon dioxide.

7. The method according to claim 1, wherein the material of said second dielectric layer is silicon dioxide.

8. The method according to claim 1, wherein said first high density plasma is formed by a first mixed gas with both low frequency radio frequency power and high frequency radio frequency power with a bias voltage on an electrostatic chuck (ESC).

9. The method according to claim 8, wherein said first mixed gas comprises a first depositing gas, a first inert gas and oxygen.

10. The method according to claim 9, wherein said first depositing gas is silane (SiH₄).

11. The method according to claim 9, wherein said first inert gas is argon.

12. The method according to claim 1, wherein said second high density plasma is formed by a second mixed gas with both low frequency radio frequency power and high frequency radio frequency power with a bias voltage on an electrostatic chuck (ESC).

13. The method according to claim 12, wherein said second mixed gas comprises a second inert gas and oxygen.

14. The method according to claim 13, wherein said second inert gas is argon.

15. The method according to claim 1, wherein said third high density plasma is formed by a third mixed gas with both low frequency radio frequency power and high frequency radio frequency power with a bias voltage on an electrostatic chuck (ESC).

16. The method according to claim 15, wherein said third mixed gas comprises a second depositing gas, a third inert gas and oxygen.

17. The method according to claim 16, wherein said second depositing gas is silane.

18. The method according to claim 16, wherein said third inert gas is argon.

19. The method according to claim 1, wherein all of said steps is performed in situ in a chamber.

20. A method for gap filling between metal-metal lines, comprising:
providing a semiconductor structure in a chamber, wherein a surface of said semiconductor structure has a plurality of metal lines thereon;
providing a first mixed gas in said chamber, wherein said first mixed gas comprises a first inert gas, a first depositing gas and a first oxidative gas;
a first high density plasma is produced from said first mixed gas to form a first dielectric layer on a surface and a side wall of said plurality of metal lines;
providing a second mixed gas in said chamber, wherein said second mixed gas comprises a second inert gas and a second oxidative gas;
a second high density plasma is produced from said second mixed gas to remove a portion of said first dielectric layer;
providing a third mixed gas in said chamber, wherein said third mixed gas comprises a third inert gas, a second depositing as and a third oxidative gas; and
a third high density plasma is produced from said third mixed gas to form a second dielectric layer on said first dielectric layer.

21. The method according to claim 20, further comprising an adhesive layer formed on said underside of said plurality of metal lines.

22. The method according to claim 20, further comprising an anti-reflection layer formed on said top of said plurality of metal lines.

23. The method according to claim 22, wherein the material of said anti-reflection layer is silicon-oxy-nitride (SiOₓN_{y}).

24. The method according to claim 20, wherein said material of said plurality of metal lines is selected from the group consisting of AlCu alloy and Al alloy.

25. The method according to claim 20, wherein the material of said first dielectric layer is silicon dioxide.

26. The method according to claim 20, wherein the material of said second dielectric layer is silicon dioxide.

27. The method according to claim 20, wherein said first dielectric with a geometric shape is remained on some of said metal lines after removing said first dielectric layer.
